(19) United States
(12) Patent Application Publication
(10) Pub. No.: US 2013/0193416 A1
(43) Pub. Date: Aug. 1, 2013

(54) ORGANIC ELECTROLUMINESCENT DEVICES AND METHODS FOR FABRICATING THE SAME

(71) Applicant: Electronics and Telecommunications Research Institute, Daejeon (KR)

(72) Inventor: Jin Wook SHIN, Incheon (KR)

(73) Assignee: ELECTRONICS AND TELECOMMUNICATIONS RESEARCH INSTITUTE, Daejeon (KR)

(21) Appl. No.: 13/733,947

(22) Filed: Jan. 4, 2013

(30) Foreign Application Priority Data
Jan. 26, 2012 (KR) 10-2012-0007478

(51) Int. Cl. H01L 51/50; H01L 51/56

(52) U.S. Cl. CPC H01L 51/50; H01L 51/56
USPC 257/40; 257/98; 438/29

(57) ABSTRACT

Provide is an organic electroluminescent device including an organic electroluminescent layer emitting a light and a plurality of nano-sized embossing layers stacked to improve light extraction efficiency of the emitted light.

### CROSS-REFERENCE TO RELATED APPLICATIONS

This U.S. non-provisional patent application claims priority under 35 U.S.C. §119 to Korean Patent Application No. 10-2012-0007478, filed on Jan. 26, 2012, in the Korean Intellectual Property Office, the entire contents of which are hereby incorporated by reference.

### BACKGROUND OF THE INVENTION

Example embodiments of the inventive concept relate to organic electroluminescent devices and methods of fabricating the same, and in particular, to organic electroluminescent devices, in which light extraction can be performed with reliability, and a method of fabricating the same.

In organic electroluminescent devices, for example, an organic electroluminescent diode, exitons are generated by a combination process, in which holes supplied from an anode electrode and electrons supplied from a cathode electrode are combined with each other in an organic electroluminescent layer provided between the electrodes, and then, be recombined to emit a light. The organic electroluminescent diode is one of self-luminous devices, and is being developed to realize a display device with a wide viewing angle, a fast response time, and a high color gamut property. Further, the organic electroluminescent diode is being studied to realize an illumination system.

FIG. 1 is a schematic diagram illustrating a stacking structure of a conventional organic electroluminescent device. The conventional organic electroluminescent device may include a substrate 10, an anode 20 serving as a transparent electrode, an organic electroluminescent layer 30, a cathode 40 serving as a reflective electrode, and a protection layer 50, which are stacked sequentially.

The organic electroluminescent diode may be configured to display one of red (R), green (G), and blue (B) or display a white light. To obtain a desired color, a plurality of organic light emitting diodes emitting lights of different wavelengths from each other may be combined with each other.

Korean Laid Open Patent Application No. 2007-0008071 proposes stacked organic light emitting structures of which widths are equal to each other. In the reference, a planar area of RGB sub-pixels having the stacked organic light emitting structures may be equal to a planar area of a pixel, such that brightness may increase and pixels may become highly fine. However, light generated from a middle sub-pixel of the stacked sub-pixels may be reflected by a lower sub-pixel and/or an upper sub-pixel and then be radiated outside the pixel. Thus, light efficiency may be reduced.

### SUMMARY

Example embodiments of the inventive concept provide organic electroluminescent devices, in which light extraction can be performed with reliability, and a method of fabricating the same.

According to example embodiments of the inventive concept, an organic electroluminescent device may include an organic electroluminescent layer emitting a light and a plurality of nano-sized embossing layers stacked to improve light extraction efficiency of the emitted light.

In example embodiments, the organic electroluminescent device may further include at least one planarization layer covering a corresponding one of the nano-sized embossing layers.

According to example embodiments of the inventive concept, a method of fabricating an organic electroluminescent device may include forming a plurality of nano structures stacked one on another, where each of the nano structures includes a nano-sized embossing layer and a planarization layer covering the nano-sized embossing layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic diagram illustrating a stacking structure of a conventional organic electroluminescent device.

FIG. 2 is a schematic diagram illustrating an organic electroluminescent device according to example embodiments of the inventive concept.

FIG. 3 is a schematic diagram illustrating a phosphorescent white OLED device with two luminescent layers.

FIG. 4 is a schematic diagram illustrating an operating principle of a triplet harvesting-type hybrid white OLED.

FIG. 5 is a schematic diagram illustrating a direct recombination-type hybrid white OLED.

FIG. 6 is a schematic diagram illustrating an optical extraction principle of a micro-lens array.

FIG. 7 is a schematic diagram illustrating a micro-resonator using a Bragg minor.

FIG. 8 is a schematic diagram illustrating an organic electroluminescent device according to example embodiments of the inventive concept.

FIG. 9 is a microscope image showing nano patterns formed by a dewetting phenomenon.

FIG. 10 is a schematic diagram illustrating an organic electroluminescent device according to other example embodiments of the inventive concept.

FIGS. 11A to 11L are schematic diagrams illustrating a method of fabricating an organic electroluminescent device according to example embodiments of the inventive concept.

FIGS. 12A to 12K are schematic diagrams illustrating a method of fabricating an organic electroluminescent device according to other example embodiments of the inventive concept.

FIGS. 13A to 13C are microscope images showing nano patterns.

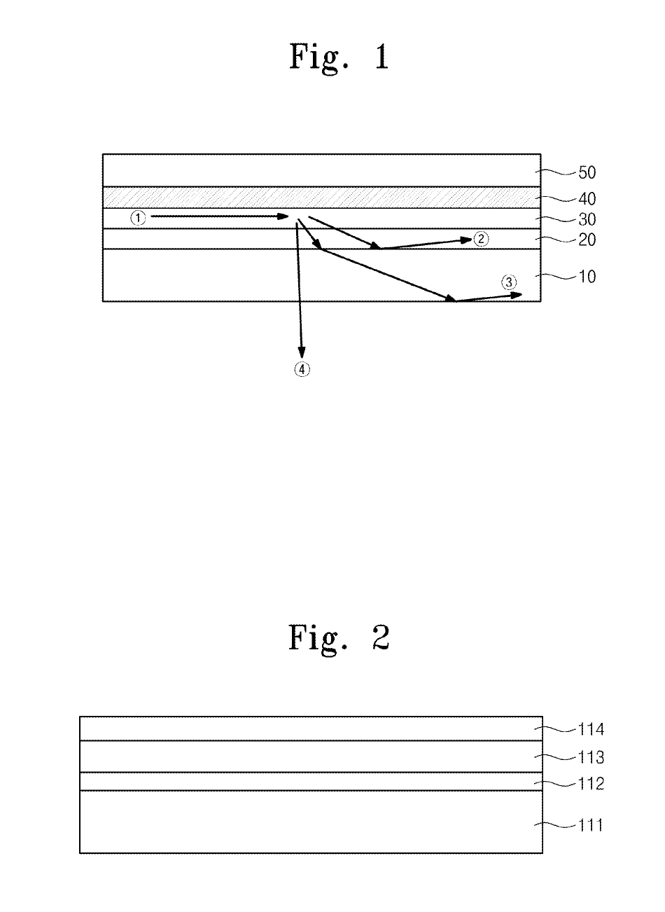

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

FIG. 2 is a schematic diagram illustrating an organic electroluminescent device according to example embodiments of the inventive concept.

Referring to FIG. 2, an organic electroluminescent device may include a substrate 111, a first electrode 112, an organic electroluminescent layer 113, and a second electrode 114, which are stacked sequentially.

The substrate 111 may serve as a mechanical supporter for the organic electroluminescent device and as a transparent window. The substrate 111 may be formed of a transparent material, such as glass or plastic. In example embodiments, the plastic for the substrate 111 may include at least one of polyethylene terephthalate (PET), polycarbonate (PC), polyethersulfone (PES), and polyimide (PI).

The first electrode 112 may be used as one of an anode and a cathode, but for the sake of simplicity, the description that follows will refer to an example of the present embodiment in which the first electrode 112 may be used as an anode. The first electrode 112 may be formed of a transparent conductive material. For example, the first electrode 112 may be formed of a transparent conductive oxide (TCO). In example embodiments, the first electrode 112 may be at least one of indium-tin oxide (ITO) or indium-zinc oxide (IZO). But example embodiments of the inventive concepts may not be limited thereto. For example, the first electrode 112 may be formed of one of several materials, such as a graphene layer or conductive polymeric materials (Pedot:Pss).

The second electrode 114 may be configured to have opposite polarity with respect to the first electrode 112. For example, if the first electrode 112 is an anode, the second electrode 114 may be a cathode, and vice versa. The second electrode 114 may be a conductive material. The second electrode 114 may be a metal or a transparent conductive material. In example embodiments, the metal for the second electrode 114 may include aluminum (Al), silver (Ag), magnesium (Mg), molybdenum (Mo), or alloys thereof. The transparent conductive material for the second electrode 114 may be realized using a metal thin film. Here, a wavelength of a light capable of transmitting the metal thin film may be changed depending on a thickness of the metal thin film.

The organic electroluminescent layer 113 may be configured to emit a light using an electric power provided between the first electrode 112 and the second electrode 114, and include an organic material. For example, the organic electroluminescent diode (OLED) is a self-luminous device, in which, when electric field is applied thereto, a light with a specific wavelength is emitted from the organic electroluminescent layer 113. The organic electroluminescent diode may include an anode layer (e.g., of ITO), a hole injection layer, a hole transfer layer, a light emitting layer, an electron transfer layer, an electron injection layer, a cathode layer (e.g., of metal), which are sequentially stacked on the substrate 111. Hereinafter, a term of “organic electroluminescent layer” will be used to refer to layers between the electrodes 112 and 114 (e.g., the hole injection layer, the hole transfer layer, the light emitting layer, the electron transfer layer, and the electron injection layer).

The organic electroluminescent layer may be used as a key element for realizing a light source. Generally, according to its structure, the organic electroluminescent layer may be classified into a stack structure, a single light emitting layer structure, a horizontal RGB structure, and a down conversion structure, and the stack structure has been widely used due to technical advantages in a fabrication process and efficiency. Further, according to its material to be used, the organic electroluminescent layer may be classified into fluorescent, phosphorescent, and hybrid white OLEDs. The fluorescent OLED has a superiority in device stability but suffers from limitation in efficiency. The phosphorescent OLED has a superiority in efficiency but suffers from a problem in displaying blue stably. To overcome these limitations in the fluorescent and phosphorescent OLEDs, there have been studied the hybrid white OLEDs, in which a fluorescent material is used to display blue color and phosphorescent materials are used to display other colors.

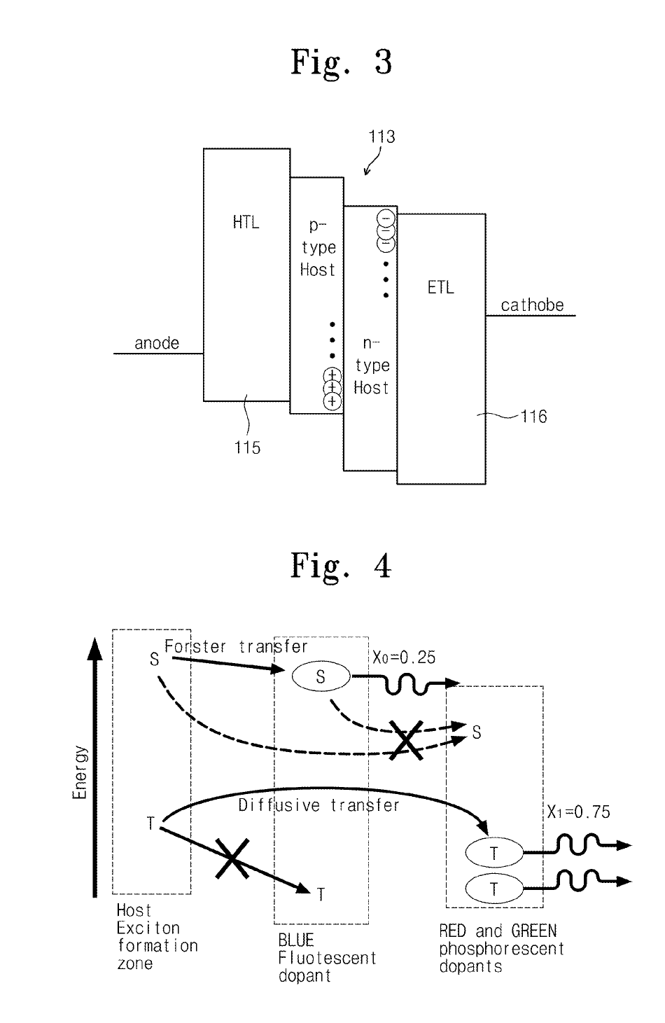

The phosphorescent device may include a hole injection/transfer layer 115, an electron injection/transfer layer 116, and two layers serving as a light emitting layer 113, similar to that of the phosphorescent white OLED device including two light emitting layers (as shown in FIG. 3). The light emitting layer 113 may include a p-Type host and an n-Type host, which may be configured to have a HOMO/LUMO structure, similar to that of a PN junction of LED, and it has a technical advantage, such as a reduction in current loss, because the recombination zone is confined within an interface between two hosts. Here, preferably, the material for this may have electrochemical/thermal stability. In addition, preferably, triplet energy of the host should be higher than that of blue phosphorescent dopant, and hole or electron mobility should not be excessively low. Further, in the case where a hole transfer layer of an electron transfer layer can be formed to have high mobility and triplet energy higher than that of blue phosphorescent dopant, the device can be designed with increased degree of freedom.

For the phosphorescent white OLED, it is need to develop a novel material having wide triplet energy and dopants capable of realizing a high color rendering index. This means that an OLED material for a light source may be different from that to be used for display panels.

Meanwhile, the blue color phosphorescent material having a stability problem is replaced with a fluorescent material in the phosphorescent white organic electroluminescent device described above, thereby forming the hybrid white organic electroluminescent device. The hybrid white organic electroluminescent device may be categorized as one of a triplet harvesting type capable of using a triplet of a fluorescent layer and a direct recombination type not capable of using the triplet of the fluorescent layer.

The triplet harvesting type may change an entire current into light energy in theory, such that it is very attractive. In other words, the triplet harvesting type organic electroluminescent device may obtain the same efficiency as the phosphorescent white organic electroluminescent device and secure the device stability, such that researchers are concerned about it. FIG. 4 shows a method of operating the triplet harvesting type hybrid white organic electroluminescent device. As illustrated in FIG. 4, electrons and holes may be mostly recombined with each other in the fluorescent layer constituting the light emitting layer, so that blue light is generated by singlet excitons of the fluorescent layer. The triplets not used in the recombination zone of the fluorescent layer may be moved into the phosphorescent layer by diffusive transfer to generate green and red phosphorescent lights. By the described principle, the singlet excitons of 25% may be converted into the blue light in the fluorescent layer and the triplet excitons of 75% may be converted into the green light and the red light in the phosphorescent layer. Thus, a converting efficiency of 100% may be obtained.

In the above device, it is important to confine the recombination zone in only the fluorescent layer and to control the diffusive transfer for using the triplet excitons in only the phosphorescent layer. However, it may be difficult to use the above type hybrid device due to the above particular operating method. In other words, the triplet excitons of the fluorescent layer may have to be moved into the phosphorescent layer without loss. However, the triplet excitons may be lost in the fluorescent layer by a non-light emitting process or be moved from the phosphorescent layer to the fluorescent layer again to be lost. Here, information for a desired path through which the triplet excitons fast passes may lack, such that it may be difficult to design the device.

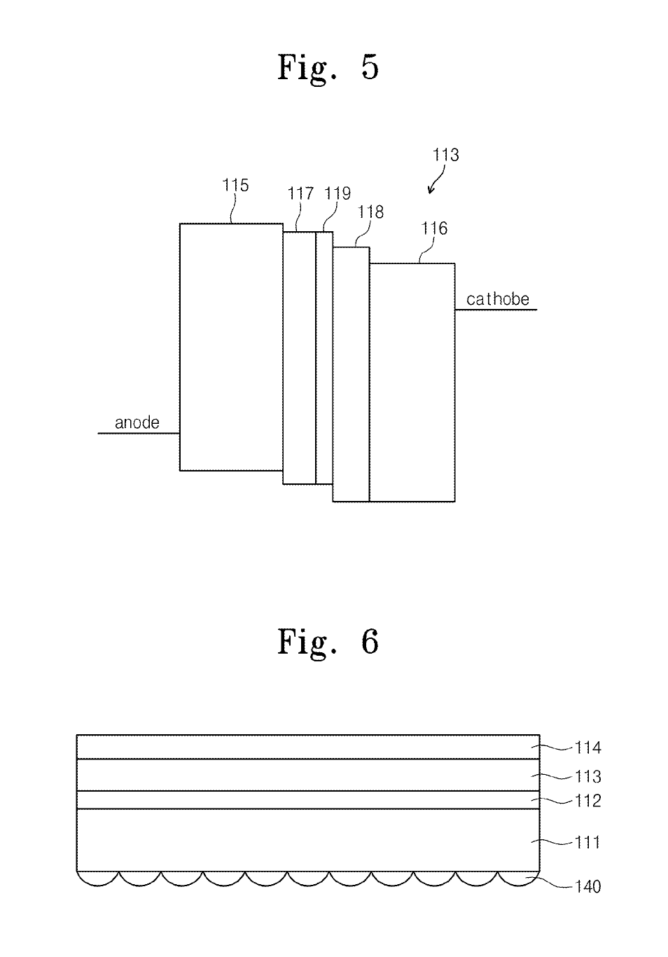

As illustrated in FIG. 5, in the direct recombination type hybrid white organic electroluminescent device, a recombination zone may be formed all of the fluorescent layer 118 and the phosphorescent layer 117. Thus, light may be omitted from all of the fluorescent and phosphorescent layers 118 and 117. Differently from the above triplet harvesting type, the direct recombination type may not use the triplet excitons of a blue fluorescent layer, such that the efficiency thereof may be low. However, the direct recombination type hybrid white organic electroluminescent device may use various materials and have high-degree of freedom in design thereof. An interlayer 119 separating the fluorescent layer 118 from the phosphorescent layer 117 may play an important part in the direct combination type hybrid white organic electroluminescent device. The interlayer 119 may control the formation of the recombination zone through the fluorescent layer 118 and the phosphorescent layer 117. Additionally, the interlayer 119 may prevent the triplet excitons of the phosphorescent layer 117 from being moved into the fluorescent layer 118.

The organic electroluminescent layer may include an organic electroluminescent material. For example, the organic electroluminescent layer may include at least one of polyfluorene derivatives, (poly)paraphenylenevinylene derivatives, polyphenylene derivatives, polyvinylcarbazole derivatives, polythiophene derivatives, anthracene derivatives, butadiene derivatives, tetracene derivatives, distyrylarylene derivatives, benzazole derivatives, or carbazole.

In addition, the organic electroluminescent layer may be a doped organic electroluminescent material. For example, the organic electroluminescent layer may include at least one of xanthene, perylene, cumarine, rhodamine, rubrene, dicyanomethylenepyran, thiopyran, (thia)pyrilium, periflanthene derivatives, indenoperylene derivatives, carbostyryl, Nile red, or quinacridone as dopants therein.

The organic electroluminescent material may include at least one of polyfluorene derivatives, (poly)paraphenylenevinylene derivatives, polyphenylene derivatives, polyvinylcarbazole derivatives, polythiophene derivatives, anthracene derivatives, butadiene derivatives, tetracene derivatives, distyrylarylene derivatives, benzazole derivatives, or carbazole.

In addition, the organic electroluminescent device such as OLED may be configured to improve efficiency in light extraction.

For the phosphorescent OLED, its internal quantum efficiency may be theoretically 100%, that is four times that of the fluorescent OLED, but it suffers from short lifetime. Although the lifetime thereof is increased, a small amount (e.g., 20%) of the generated light is emitted to the outside, and the remaining light is not emitted to the outside, as a result of a wave-guiding effect caused by a difference in refractive index among the substrate 111, the first electrode 112, and the organic electroluminescent layer 113 and a total reflection effect caused by a difference in refractive index between the substrate 111 and the air.

For example, the organic electroluminescent layer has a refractive index of 1.6-1.9, and the ITO layer serving as the anode has a refractive index of about 1.8-2.0. Thicknesses these two layers are thin (e.g., of about 100-400 nm), and glass to be widely used for the substrate has a refractive index of 1.5. Accordingly, a planar waveguide may be formed in OLED. According to the calculation, a major part (e.g., 45%) of a generated light may be lost as the result of internal propagating mode caused by the planar waveguide. In addition, the substrate has a refractive index of about 1.5 and the external air has a refractive index of 1.0, a part (e.g., 35%) of the generated light is isolated or trapped in the internal region by total reflection. Accordingly, a small amount (e.g., 20%) of the generated light may be emitted to the outside.

Given the low light extraction efficiency, a light extraction technique is important to improve efficiency, brightness, and lifetime of OLED panels for a light source.

An internal light extraction may refer to a technique emitting an isolated light in the organic light emitting layer/ITO layer, which is caused by the difference in refractive index between the anode (e.g., of ITO) and the substrate, to the outside, while an external light extraction may refer to a technique emitting an isolated light in the substrate to the outside (e.g., air).

The external light extraction may be realized using at least one of a micro-lens array (MLA), an external light scattering layer, or a formation of an anti-reflective film.

The internal light extraction technique may theoretically improve external light efficiency by three or more times. However, the internal light extraction technique may sensitively influence an internal interface in the organic electroluminescent device, such that electrical, mechanical, and chemical properties as well as the optical effect should be satisfied. The internal light extraction may be realized using at least one of an internal light scattering layer, a substrate surface deformation, a refractive index controlling layer, photonic crystals, or nanostructure formation.

The micro lens array of the external light extraction may include small lenses, which have a diameter less than 1 mm and be two-dimensionally arranged on a surface of the substrate facing the air. As illustrated in FIG. 6, the micro lens 140 of the micro lens array has a curved surface. Thus, an incident angle of light with respect to a surface tangent line of the micro lens 140 is smaller than the critical angle, so that the light is not total-reflected. As a result, the light is not confined in the substrate and is extracted to the outside of the organic electroluminescent device. The micro lens array may be formed of a material having the same refractive index as the substrate 111. A diameter of the micro lens 140 may be several tens μm. As a density of micro lens 140 increases, light extraction efficiency may increase. Light distribution may be varied depending on a shape of the micro lens. The external light extraction structure using the micro lens array may be bonded to the substrate to increase efficiency by about 50%.

The external light scattering layer in the external light extraction may be formed to have a sheet-shape and then be bonded to the substrate similarly to the micro lens array. Alternatively, a solution for the external light scattering layer may be coated on the substrate and then be hardened to form the external light scattering layer. The external light scattering layer may not cause color variation according to a view angle and an interference color. The light distribution of the light passing through the external light scattering layer may maintain Lambertian distribution. The external light scattering layer may have a good structure applied to a white OLED lighting panel. However, if the external light scattering layer becomes thicker and light scattering particles are formed to have a multi-layered structure, a scattering effect of light having a short wavelength may be greater than that of light having a long wavelength, so that transmitted light may have a yellowish red color. A refractive index, a size, and a density of scattering particles and a refractive index and absorption spectrum of the material should be controlled for minimizing spectrum variation caused by the scatting effect difference according to the wavelength of light. In an external fluorescent colloid structure, a ratio of absorbed light and scattered re-emitted light may be sensitively varied depending on a thickness, a size, a concentration of the fluorescent material. Thus, the external fluorescent colloid structure may be carefully designed. It may be effective that the external light scatting layer may be formed using a polymer sheet containing small air bubbles. Difference between the refractive index (i.e., 1.0) of the air bubble and the refractive index (e.g., about 1.5) of the material may be great, so that light scattering effect may greatly occur. Thus, the thickness of the external light scattering layer may be reduced and spectrum variation may be minimized

Then anti-reflective film of the external light extraction may be formed a section of an optical device for preventing light reflection caused by sudden refractive index variation at the section of the optical device and for increasing the amount of transmitted light. The anti-reflective film may include one, two, or three layers. When light is incident to and transmitted through a glass substrate, the light may be reflected twice, such that light of 8% may be lost by the reflection. However, the light may be reflected once in the organic electroluminescent device due to the structure thereof when the light is outputted to the external air. Thus, the light extraction efficiency of about 4% may increase if the anti-reflective film is used for the external light extraction. In order that reflection of vertically incident light of a single wavelength is minimized, a material having a refractive index equal to the square root of a refractive index of the substrate may be deposited on the substrate with a thickness equal to a quarter of the single wavelength. However, several layers having different materials from each other should be deposited on the substrate in order that reflecting rates of lights of several wavelengths such as a visible ray region are minimized

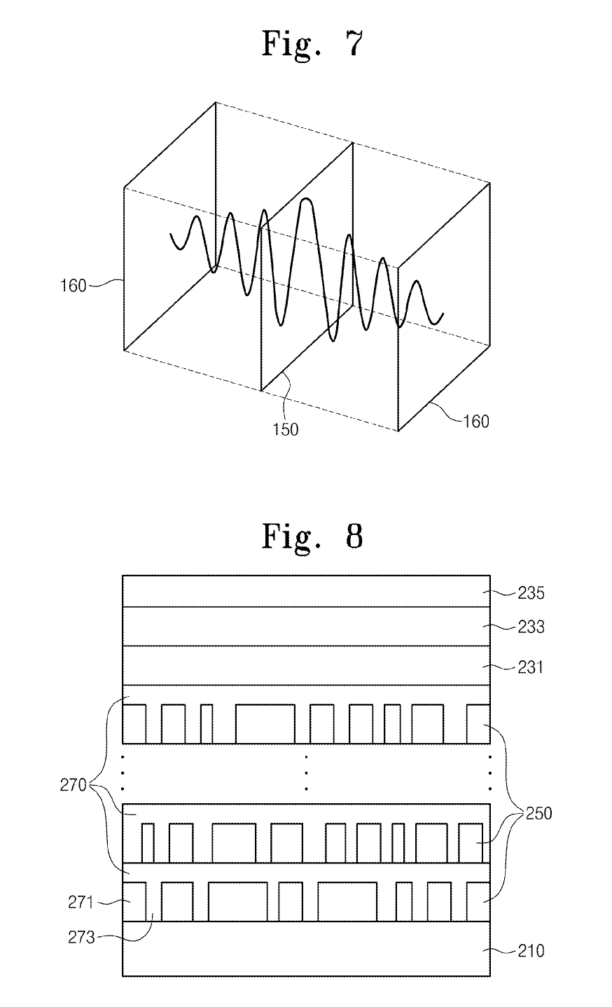

A micro-resonance of the internal light extraction is called ‘micro cavity’. As illustrated in FIG. 7, the micro-resonance may be caused by two Bragg minors 160 (or two metal minors) and a spacer layer 150 disposed between the two Bragg minors 160.

A thickness of the spacer layer 150 may be substantially equal to a wavelength for generating a standing wave of a visible ray. Thus, resonance of the internal light extraction is called as the micro-resonance. In the organic electroluminescent device, the micro-resonance may include a strong cavity and a weak cavity. The organic electroluminescent device may have the weak cavity without a specific design for a resonance structure. In other words, since the organic electroluminescent device includes the ITO anode having the refractive index of about 1.9, the metal cathode having the refractive index of about 1.9, and the organic light emitting layer disposed between the ITO anode and the metal cathode. The light emitting layer has the refractive index within a range of about 1.6 to 1.9 and the thickness of several hundreds nm. Thus, the organic electroluminescent device may naturally have the micro-resonance structure. As a result, the light extraction efficiency may be greatly changed depending on the thickness of the organic light emitting layer and the thickness of the ITO anode. Particularly, a ratio of the light extraction mode to the internal/external guided mode may be changed from about 22% to about 55% as a relative position of the recombination zone is changed.

Additionally, if a thickness of the cathode is greater than λ/4 where λ is a wavelength of light, the light extraction efficiency may be reduced. Thus, the thickness of the cathode may be equal to or less than λ/4.

A tandem structure using a multi-layered organic light emitting layer may use various micro-resonance structures, so as to be used in a method of manufacturing a color modulation OLED panel. For forming the micro-resonance structure, a Bragg minor layer may be deposited before the layers of the organic electroluminescent devices are deposited, and thicknesses of the layers of the organic electroluminescent device may be controlled. Thus, surface defects may not be caused by the micro-resonance structure, such that the micro-resonance structure may be easily applied to mass production of the panels. However, it may be difficult to use the micro-resonance structure to the internal light extraction of the OLED lighting panel. This is because the micro-resonance may cause spectrum narrowing. As the strong cavity is used, the spectrum may be narrower. Thus, only light of very narrow wavelength region may be strongly emitted, and emitting efficiency of light of wavelengths except the corresponding wavelength region may be reduced.

If the micro-resonance structure is used in the OLED lighting panel using the white organic electroluminescent device, the color of light emitted from the panel may deviate from a white range and the light extraction efficiency of the light of wavelengths except a specific wavelength may be reduced. It is preferable to apply the micro-resonance effect to a display panel emitting lights of RGB colors individually or an OLED panel emitting light of a single color.

The photonic crystal of the internal light extraction may include two materials having dielectric constants different from each other, which are arranged on a nanometer-scale with a regular period. The photonic crystal may allow light to be transmitted or forbidden depending on the wavelength of the light. Thus, the photonic crystal may transmit the light of a specific wavelength. Here, the forbidden wavelength region is defined as a photonic band gap. It is possible to manufacture an optic device using the above phenomenon and capable of changing a light path without loss. The photonic crystal may be categorized as one of a one-dimensional photonic crystal called ‘Bragg grating’, a two-dimensional photonic crystal including protrusions of an embossing structure arranged with a regular period on a plane, and a three-dimensional photonic crystal. The photonic crystal may use light diffraction. In other words, the photonic crystal may be provided on a planar waveguide formed in the organic electroluminescent device for preventing light from being transmitted in a planar direction, thereby forming a forbidden band. Thus, the light emitted from the organic light emitting layer may not form a guided mode and may be outputted outside. The two-dimensional photonic crystal using this phenomenon may be formed in the organic electroluminescent device to increase the light extraction efficiency. The photonic crystal may be applied to a single color light OLED. However, if the photonic crystal is applied to the OLED lighting panel using the white OLED, only the light extraction efficiency of light having a specific wavelength may increase.

The internal light scattering layer of the internal light extraction may not cause color variation according to a view angle and may maintain Lambertian distribution like the external light scattering layer. Thus, the brightness of the panel using the internal light scattering layer may be uniform. For forming the internal light scattering layer, materials having refractive indexes different from each other may be mixed and then the mixed materials may be coated on a glass substrate. Thus, the internal light scattering layer may be relatively easily formed. If the internal light scattering layer is applied, the light extraction efficiency may increase, the color variation according to the view angle may decrease, and the light distribution of the organic electroluminescent device may be close to the Lambertian distribution. The number of scattering centers should increase for increasing the light scattering effect. However, if the number of scattering centers is too increased, a back scattering effect may increase. Thus, the scattering light may be absorbed in the organic light emitting layer again. Thus, the scattering degree and the internal absorption should be optimized to increase the light extraction efficiency if the light is not absorbed in the light scattering layer. However, if the light is absorbed in the light scattering layer, the increase amount of the light efficiency by the light extraction effect may be reduced by the absorption of the light scattering layer. If an absorbance in the light scattering layer is 0.1, a light efficiency drop caused by the absorption may be greater than the light extraction effect. Thus, for using the internal light scattering layer as the internal light extraction structure, the internal light scattering layer may be thin in order that the absorbance of the light scattering is less than 0.1.

The nano-sized embossing structure of the internal light extraction may be a light extraction structure using advantages of the photonic crystal and the light scattering layer. As described above, the photonic crystal structure may be used for only the specific wavelength band, such that it may not be used in the white OLED. The light scattering layer may cause the internal absorption to decrease the light extraction effect. Similar to the photonic crystal, the nano-sized embossing structure may include a nano-sized embossing structure (e.g., with several hundreds nm) to be used for the internal light extraction structure. However, protrusions of the nano-sized embossing structure may be irregularly arranged. The nano-sized embossing structure having this arrangement may partially cause the diffraction effect and function as a single-layered light scattering layer. Thus, the nano-sized embossing structure may substantially remove dependence on the wavelength, the color variation caused by the view angle, distortion of the light distribution. Additionally, the self-absorption of the nano-sized embossing structure may be disregarded.

FIG. 8 is a schematic diagram illustrating an organic electroluminescent device according to example embodiments of the inventive concept.

Referring to FIG. 8, an organic electroluminescent device may include an organic electroluminescent layer 233, which is configured to emit a light, and a plurality of nano-sized embossing layers 250, which are stacked to improve light extraction efficiency of the emitted light.

In particular, as shown in FIG. 8, the organic electroluminescent device may include a plurality of the nano-sized embossing layers 250, a first electrode 231, the organic electroluminescent layer 233, and a second electrode 235, which are sequentially stacked on a substrate 210. In example embodiments, at least one additional layer may be interposed between at least one of pairs of the layers to perform additional function(s). The first electrode 231 may serve as an anode, and the second electrode 235 may serve as a cathode. Positions of the anode and the cathode may be inverted. In addition, the organic electroluminescent device may be configured not to include the substrate 210.

Each of the nano-sized embossing layers 250 may be configured to have substantially the same technical features as the afore-described nano-sized embossing structure and be interposed between the substrate 210 and the first electrode 231. Each of the nano-sized embossing layers 250 may include at least one convex portion 271 and at least one concave portion 273, in sectional view. The concave portion 273 may be provided to have a hole, groove, or dent structure. In the case where the concave portion 273 is shaped like a hole, the concave portion 273 may be formed to expose the substrate 210 or a planarization layer 270 thereunder. In the case where the concave portion 273 is shaped like the groove or dent, the concave portion 273 may be formed not to expose the substrate 210 or planarization layer 270. The concave portion 273 may be provided to have a mixed structure including both of hole-like and dent-like portions.

To improve the efficiency of light extraction, as described above, the organic electroluminescent device may be configured to include the plurality of nano-sized embossing layers 250.

Each of the nano-sized embossing layers 250 may be formed using dewetting phenomenon of a metal layer and a dry etching process (e.g., reactive ion etching process). In certain embodiments, a wet etching process may be used along with the dry etching process.

Specifically, the formation of the nano-sized embossing layer may include coating a high refractive index medium layer on a substrate (e.g., an organic substrate) or on the additional layer provided on the substrate, and depositing a metal layer on the high refractive index medium layer. Thereafter, a thermal treatment may be performed to induce the dewetting phenomenon of the metal layer and form nano-sized patterns having a size ranging from several tens to several hundreds nanometers. The nano patterns may serve as an etch mask in a process of etching the high refractive index medium layer. Thereafter, a reactive ion etching process (e.g., using oxygen plasma) may be performed to etch the high refractive index medium layer, such that the high refractive index medium layer may have a patterned structure transferred from the nano patterns. Thereafter, an etching process may be performed (for example, using nitric acid) to remain the high refractive index medium layer pattern and remove the nano patterns, and consequently, a portion of the high refractive index medium layer serving as the nano-sized embossing layer may remain on the substrate.

A shape of each nano pattern may be changed by adjusting process parameters (for example, thickness or material of the metal layer, process conditions (e.g., temperature, duration time, and ambient gas) of thermal treatment, material of the high refractive index medium layer, and conditions in a surface treatment process to be performed to the high refractive index medium layer). For example, the nano pattern may be formed to have at least one of a droplet-like structure, a porous structure, a mesh-like structure, or a structure including randomly mixed comb patterns.

Due to the presence of the nano-sized embossing layer provided with the nano patterns, a light emitted from the organic electroluminescent layer may be scattered, diffusedly reflected, and/or refracted to emit toward the outside of the substrate, not toward the first electrode.

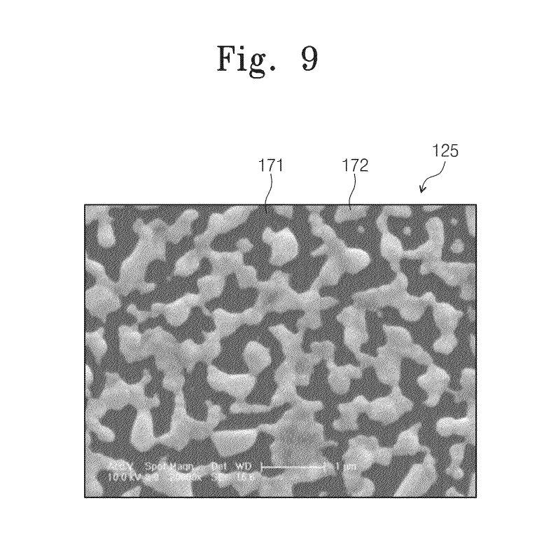

FIG. 9 is a microscope image showing nano patterns formed by a dewetting phenomenon.

A SiO₂ layer was deposited on a soda-lime organic substrate to have a thickness of 500 nm. A silver layer or a silver-alloy layer was deposited thereon to have a thickness of 30 nm, and then the resulting structure was heated to 300-500 Celsius degrees for 10 minutes (for example, using a hot plate). FIG. 9 shows the resulting structure.

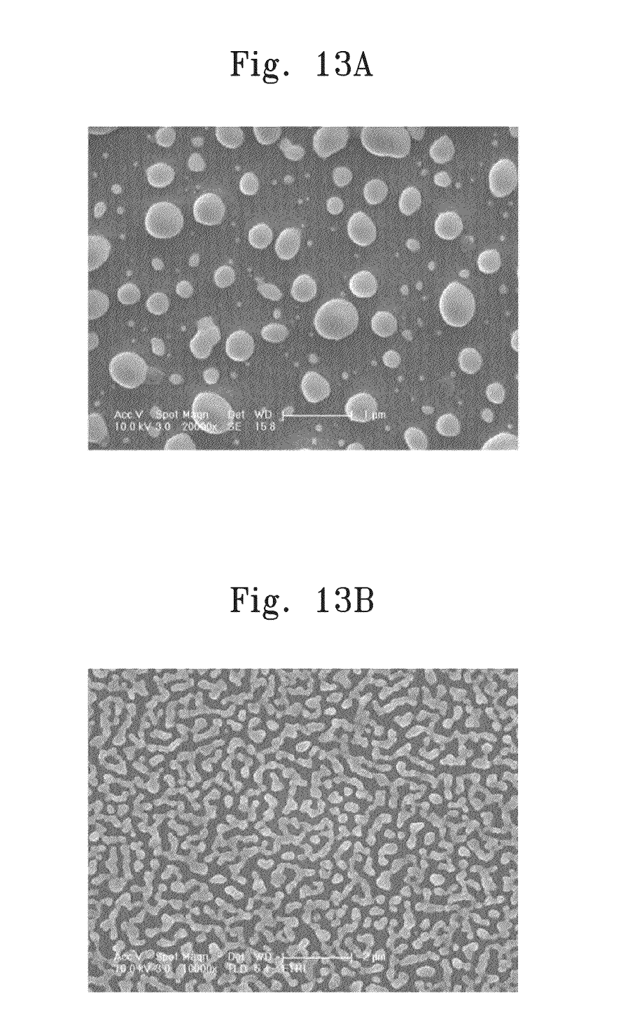

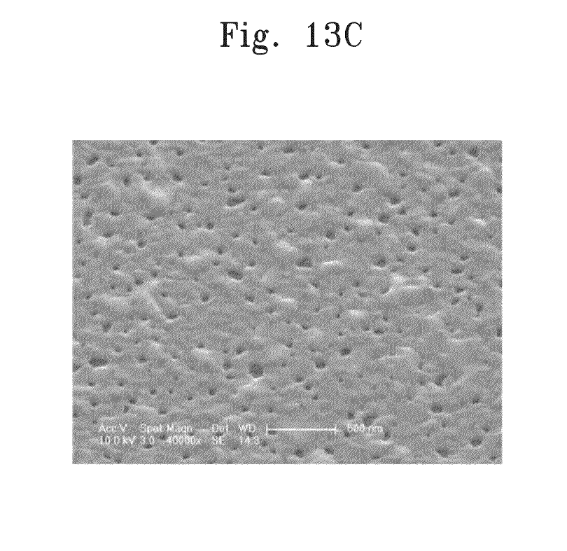

As the result of dewetting phenomenon, the metallic Ag—Pd alloy cohered to form convex portions 172 defining randomly distributed openings 171. As shown in FIGS. 13A to 13C, the convex portions 172 were formed to have a droplet shape (as shown in FIG. 13A), a concavo-convex shape (as shown in FIG. 13B), or a porous shape (as shown in FIG. 13C).

The convex portion 271 of the nano-sized embossing layer may be formed at positions of the convex portions 172, and the concave portion 273 of the nano-sized embossing layer may be formed at positions of the openings 171. In other words, the nano-sized embossing layer 250 can be easily fabricated by using nano patterns 125, which are formed using the dewetting phenomenon, as a mask.

The nano-sized embossing layer 250 provided with the random nano patterns may serve as a light scattering layer. Due to the random distribution of the nano patterns, it is possible to overcome technical problems, such as dependence on a light wavelength, color dependency on a viewing angle, distortion of light distribution, and self-absorption.

In addition, from the inventor's experiment, it is possible to further improve the light extraction efficiency, in the case where the nano-sized embossing layers are repeatedly stacked to form a multi-layered structure.

However, if the convex portion 271 of the nano-sized embossing layer 250 is formed to have an excessively small width, the light scattering effect may vanish. Further, this problem may occur when a space between the convex portions 271 is excessively small. In addition, the light extraction efficiency was decreased, even when the convex portions 271 have width and space that are uniform or regular. Accordingly, the nano-sized embossing layer 250 may be preferably formed in such a way that at least one of width and space of the convex portions 271 is random or non-uniform. In the case where the dewetting phenomenon is used to form the nano-sized embossing layer 250, the convex portion 271 can be naturally formed to have random width and random space. In other words, the formation of the nano-sized embossing layer 250 may be performed to control a process condition on the dewetting phenomenon, in order to obtain a desired width of and a desired space between the convex portions 271.

In example embodiments, the width of the convex portion 271 may range from about 100 nm to about 1000 nm, to improve the light extraction efficiency. Further, the space between the convex portions 271 may range from about 100 nm to about 3000 nm. From the inventor's experiment, a light scattering effect can be achieved with reliability, when the nano-sized embossing layer 250 is formed to have the above-described width and space of the convex portion 271.

The nano-sized embossing layer 250 may be configured to include at least one of SiO₂, SnO₂, TiO₂, TiO₂—SiO₂, ZrO₂, Al₂O₃, HfO₂, In₂O₃, ITO, nitride, polyethylene resin, poly acryl resin, polyvinyl chloride (PVC) resin, polyvinylpyrrolidone (PVP), polyimide resin, polystyrene resin, epoxy resin, or silicone resin. The nitride may include silicon nitride. The high refractive index medium layer may be formed to have a thickness ranging from 100 nm to 2000 nm.

In the case where a plurality of the nano-sized embossing layers 250 are provided, the nano-sized embossing layers 250 may be formed in such a way that the convex and concave portions 271 and 273 thereof are positioned with the same size and at the same position as each other. However, this requirement may not be satisfied when the dewetting phenomenon is used to form the nano-sized embossing layers 250. As a result, there are several technical problems. For example, the nano-sized embossing layers 250 may not be stacked in a face-to-face manner. In addition, the first electrode, stacked on the uppermost one of the nano-sized embossing layers 250, may be also formed to have a concavo-convex surface. This may lead to an uneven surface profile of the organic electroluminescent layer, which may result in electrical problems, such as current crowding or leakage current.

To overcome these technical problems, the organic electroluminescent device may further include at least one planarization layer 270 covering the nano-sized embossing layer 250, as exemplarily shown in FIG. 8.

Due to the presence of the planarization layer 270, it is possible to planarize a top surface of the resulting structure including each nano-sized embossing layer 250. In example embodiments, the planarization layer 270 may have a thickness greater than that of the convex portion 271. In other embodiments, to improve the light extraction efficiency, the planarization layer 270 may be formed to have a thickness smaller than that of the convex portion 271.

The planarization layer 270 may include at least one of inorganic materials, polymers, or composites of the inorganic material and the polymer. The inorganic materials may include at least one of TiO₂, TiO₂—SiO₂, ZrO₂, ZnS, SnO₂, or In₂O₃. The polymers may include at least one of polyvinyl phenol resin, epoxy resin, polyimide resin, polystyrene resin, polycarbonate resin, polyethylene resin, PMMA resin, polypropylene resin, or silicone resin.

The planarization layer 270 may have a refractive index ranging from 1.2 to 2.5. The uppermost one of the planarization layers 270 may be formed to have substantially the same refractive index as that of the first electrode 231, and this enables to reduce a light loss, which may result from a difference in refractive index therebetween. If the first planarization layer is used as a medium layer for forming a second nano-sized embossing layer, a refractive index of the second planarization layer may be higher, by 0.1 or more, than that of the second nano-sized embossing layer.

The uppermost one (e.g., located below the first electrode 231 in FIG. 8) of the planarization layers 270 may have a refractive index ranging from 1.7 to 2.5. This is because the first electrode 231 has a refractive index of 1.8-2.0. In order to reduce reflection from an interfacial surface of each layer, the uppermost one of the planarization layers 270 may have a refractive index of 1.9 or more. However, according to the inventor's experiment, this reduction of reflection or a desired light extraction effect may be effectively achieved in the case of the refractive index of 1.7 or more. It is conjectured that this unexpected phenomenon results from a tiny light scattering caused by an uneven surface of the planarization layer 270.

According to example embodiments of the inventive concept, the nano-sized embossing layer 250 may be used to scatter a propagation mode of light incident from a high-refractive medium into a low-refractive medium. However, if the nano-sized embossing layer 250 has a refractive index higher than that of the planarization layer 270, the light scattering effect may be reduced by the presence of the nano-sized embossing layer 250. In this sense, each planarization layer 270 may be formed to have a refractive index higher than that of the corresponding one of the nano-sized embossing layers 250 covered therewith. For example, the planarization layer 270 may have a refractive index that is higher by 0.1 or more than that of the nano-sized embossing layer 250. In example embodiments, the larger such a difference in refractive index, the more the effect of the light scattering.

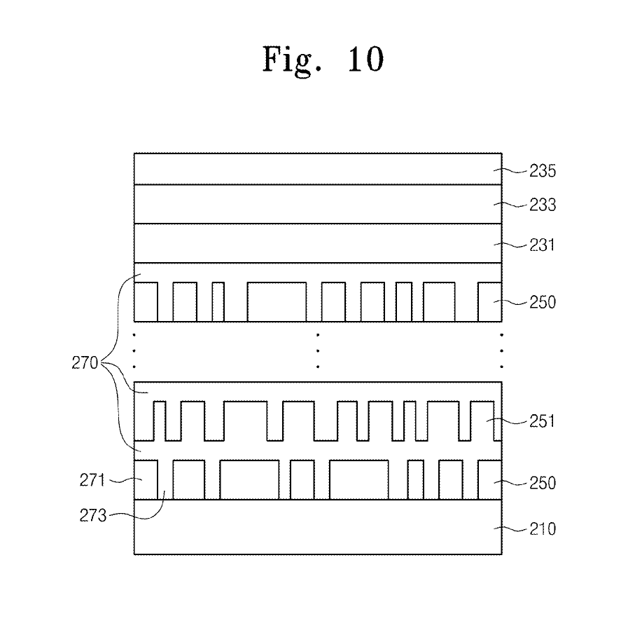

FIG. 10 is a schematic diagram illustrating an organic electroluminescent device according to other example embodiments of the inventive concept.

An organic electroluminescent device shown in FIG. 10 may be configured in such a way that at least one (e.g., 251) of the nano-sized embossing layers 250 may be formed to constitute a single body in conjunction with the planarization layer 270.

In this case, since the nano-sized embossing layer 251 and the planarization layer 270 thereunder form a single body having the same effective refractive index and enabling to improve productivity. In other words, in the case where the nano-sized embossing layer 251 is formed without the use of the high-refractive index medium, a process of forming the high-refractive index medium may be omitted. In example embodiments, the second planarization layer may be preferably formed of a material having higher than that of the nano-sized embossing layer 251.

According to example embodiments of the inventive concept, the organic electroluminescent device may include a plurality of nano structures, in which the nano-sized embossing layer and the planarization layer thereon are provided.

As a result, the light scattering effect may be multiplied to improve the light extraction efficiency. The number of the nano-sized embossing layers may be two or more, and according to the inventor's experiment, the light extraction effect can be greatly improved even when the number of the nano-sized embossing layers is two.

An external light extraction part may be formed on a surface of the substrate 111 opposite to the first electrode 112 (Refer to FIG. 2). The external light extraction part may be provided in the form of one of the micro-lens array (MLA), the external light scattering layer, the anti-reflective film, or micro concavo-convex patterns.

The formation of the MLA may include forming the MLA on a film having the same or similar refractive index as that of the substrate, and attaching it on the substrate. In other embodiments, the MLA may be formed by patterning the substrate.

In the case where concavo-convex patterns are formed on an external surface of the substrate to have a desired width, a desired height, and a desired space, it is possible to achieve the same effect as the case of forming the MLA. The concavo-convex pattern may be shaped like a pyramid, a pillar, a wavy pattern, or an irregular pattern. The concavo-convex pattern may be formed using a film-attaching method, like as the MLA, or using a method of patterning the substrate.

In the case where the light scattering layer is formed on the substrate, an amount of a light emitted to the outside can be increased, as the result of the light scattering. The light scattering layer may be formed of a material mixed with a high-refractive material and a low-refractive material. In example embodiments, the high-refractive material may be used as a main material, while the low-refractive material may be added in the form of scattering particles therein. The high-refractive material may have a refractive index that is equivalent to or slightly higher than that of the substrate.

The anti-reflective film may be provided in the form of a single- or multi-layered structure including a low refractive film. The use of the anti-reflective film enables to improve the light extraction efficiency.

According to example embodiments of the inventive concept, the internal light extraction may be realized using, for example, the nano-sized embossing layer, and the external light extraction may be realized using, for example, the MLA and so forth. Accordingly, it is possible to improve optical efficiency of the organic electroluminescent device.

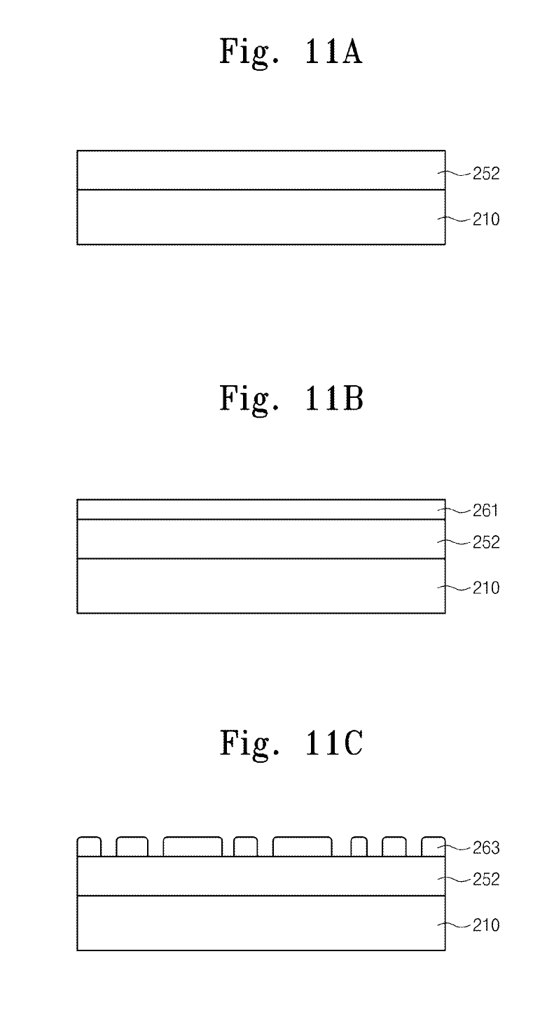

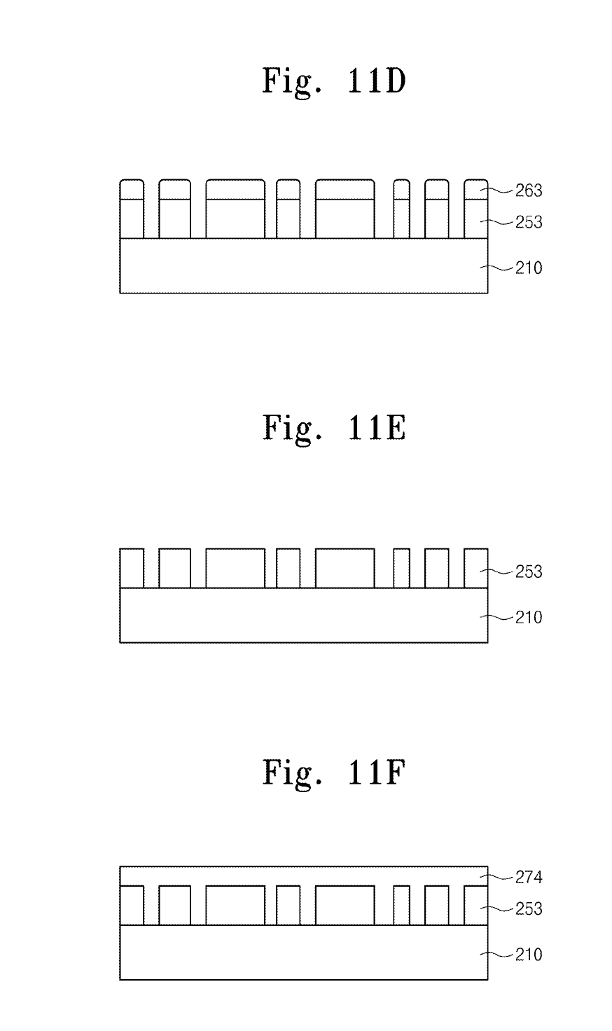

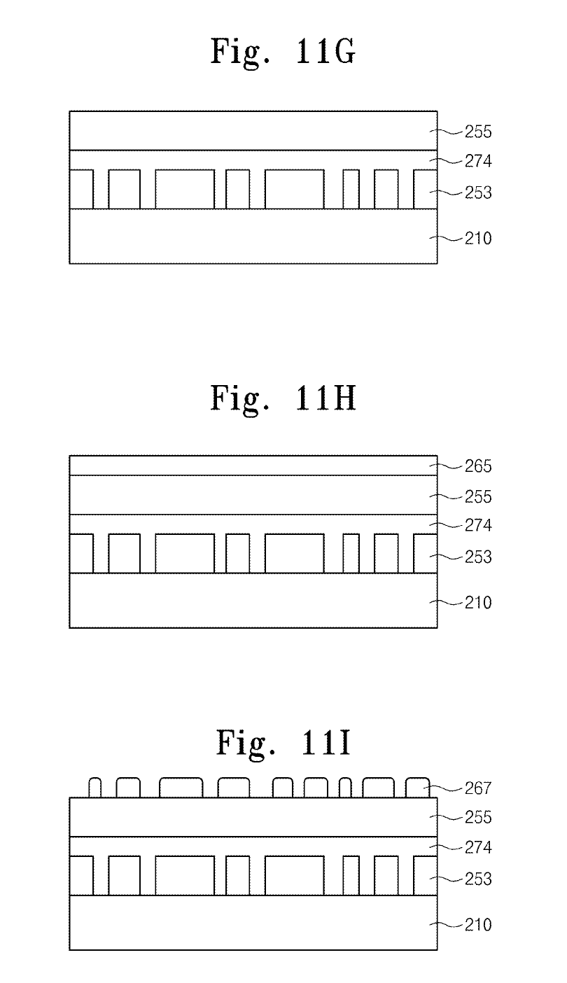

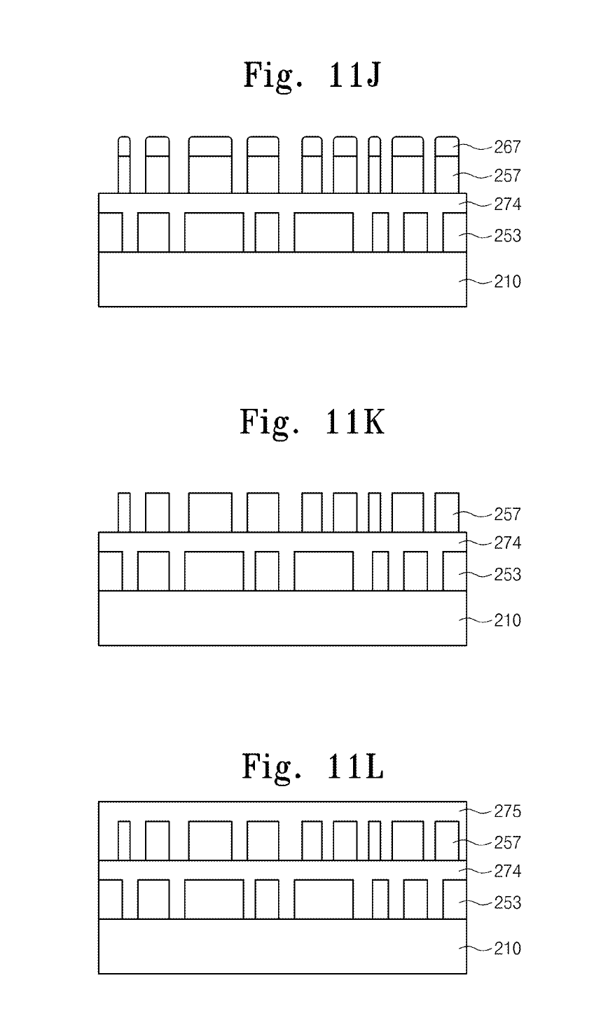

FIGS. 11A to 11L are schematic diagrams illustrating a method of fabricating an organic electroluminescent device according to example embodiments of the inventive concept.

Firstly, referring to 11L, a first nano-sized embossing layer 253 may be deposited on the substrate 210.

The first planarization layer 274 may be deposited on the first nano-sized embossing layer 253.

A second nano-sized embossing layer 257 may be deposited on the first planarization layer 274.

The second planarization layer 275 may be deposited on the second nano-sized embossing layer 257.

The above process may be repeated to form two or more layered structure including the nano-sized embossing layers and the planarization layers.

For example, a detailed process may be as follows:

Referring to 11A, the first high refractive index medium layer 252 may be deposited on the substrate 210. The substrate 210 may be formed to include a glass layer, a quartz layer, or a transparent plastic layer. The high refractive index medium layer 252 may be deposited using one of sputtering, chemical vapor deposition (CVD), E-beam evaporation, thermal evaporation, or atomic layer deposition (ALD).

Referring to 11B, a first metal layer 261 may be deposited on the first high refractive index medium layer 252.

Referring to 11C, the first metal layer 261 may be thermally treated, and thus, a first nano pattern 263 may be formed as the result of a dewetting phenomenon. In example embodiments, the first metal layer 261 may be heated by heating the substrate 210 provided with the first high refractive index medium layer 252 and the first metal layer 261. A surface energy of the first metal layer 261 may be higher than that of the first high refractive index medium layer 252, and the melting point of the first metal layer 261 may be lower than softening temperatures of the substrate 210 and the first high refractive index medium layer 252. The first metal layer 261 may be formed of a material having high etch selectivity with respect to the first high refractive index medium layer 252.

The first metal layer 261 may include one of Ag, Au, Cu, Pt, Ni, Cr, Pd, Mg, Cs, Ca, Sn, Sb, Pb, or any combination thereof. The first metal layer 261 may be formed to have a thickness ranging from 5 nm to 300 nm, and this enables to induce the dewetting phenomenon with ease.

In example embodiments, process conditions of the thermal treatment process (e.g., temperature, duration) may be controlled to adjust shape, size, or space of the convex portion constituting the nano pattern. For example, as the result of this control, the convex portion may be formed to have a droplet shape.

The thermal treatment process may be performed using one of a thermal annealing technique, a rapid thermal annealing (RTA) technique, an oven technique, and a hot-plate thermal treatment technique. The thermal treatment process may be performed at a temperature that is lower than the softening temperatures of the substrate 210 and the first high refractive index medium layer 252.

The thermal treatment process on the first metal layer 261 may be performed in the same manner on the others (e.g., the first metal layer, the second metal layer, and so forth).

Referring to 11D, the first high refractive index medium layer 252 may be etched using the first nano pattern 263 as an etch mask, thereby forming the first nano-sized embossing layer 253. This may be performed using a dry etching process or a wet etching process. The dry etching process may be performed using one of a reactive ion etching (RIE) or an inductively coupled plasma (ICP) etching. The wet etching process may be performed using hydrofluoric acid or buffered oxide etchant (BOE).

Referring to 11E, the first nano pattern 263 may be removed from the first nano-sized embossing layer 253. An acid may be used to remove the first nano pattern 263, without any damage on the first nano-sized embossing layer 253. For example, HNO₃, H₂SO₄, aqua regia, H₃PO₄ may be used in the removal of the first nano pattern 263.

According to the afore-described embodiments, the first nano-sized embossing layer 253 having a high refractive index may be formed on the substrate 210, but example embodiments of the inventive concepts may not be limited thereto. For example, the first nano-sized embossing layer 253 may be formed by patterning or processing the substrate 210, such that the first nano-sized embossing layer 253 may be provided as a part of the substrate 210.

Referring to 11F, the first planarization layer 274 may be deposited on the first nano-sized embossing layer 253. The first planarization layer 274 may be formed using one of a spin coating, a deep coating, or a spray coating. For this, the material for the first planarization layer 274 may be provided in the form of liquid solution. For example, an inorganic material may be prepared as a precursor using a sol-gel process. A composite of polymer and inorganic material may be prepared in the liquefied form by dispersing nano particles into a solvent and adding a corresponding monomer or polymer therein. In the case of using the coating process, the first planarization layer 274 may be cured by a thermal treatment or an exposure of ultraviolet light. In other embodiments, the first planarization layer 274 may be formed using one of sputtering, chemical vapor deposition (CVD), E-beam evaporation, thermal evaporation, or atomic layer deposition (ALD).

Referring to 11G, a second high refractive index medium layer 255 may be deposited on the first planarization layer 274.

Referring to 11H, a second metal layer 265 may be deposited on the second high refractive index medium layer 255.

Referring to 11I, the second metal layer 265 may be thermally treated, and thus, a second nano pattern 267 may be formed as the result of the dewetting phenomenon.

Referring to 11J, the second high refractive index medium layer 255 may be etched using the second nano pattern 267 as an etch mask to form the second nano-sized embossing layer 257.

Referring to 11K, the second nano pattern 267 may be removed.

Referring to 11L, the second planarization layer 275 may be deposited on the second nano-sized embossing layer 257.

As the result of the above processes, the organic electroluminescent device may be fabricated to have the structure shown in FIG. 8.

The nano-sized embossing layer may be configured in such a way that it's absorptivity on a visible light is lower than 10%, in order to prevent the light extraction efficiency from being deteriorated.

According to the afore-described fabrication process, a plurality of the nano-sized embossing layers 253 and 257 are stacked on the substrate 210, and the light scattering effect may actively occur as the number of the nano-sized embossing layers increases. Accordingly, the light extraction efficiency can be improved.

In certain embodiments, an additional process may be performed to form a micro-lens array (MLA), a light scattering layer, an anti-reflective film, or micro concavo-convex patterns on the substrate. This additional layer or patterns may constitute an external light extraction part and be preferably provided on a surface of the substrate 111 opposite to the first electrode 112 (Refer to FIG. 2).

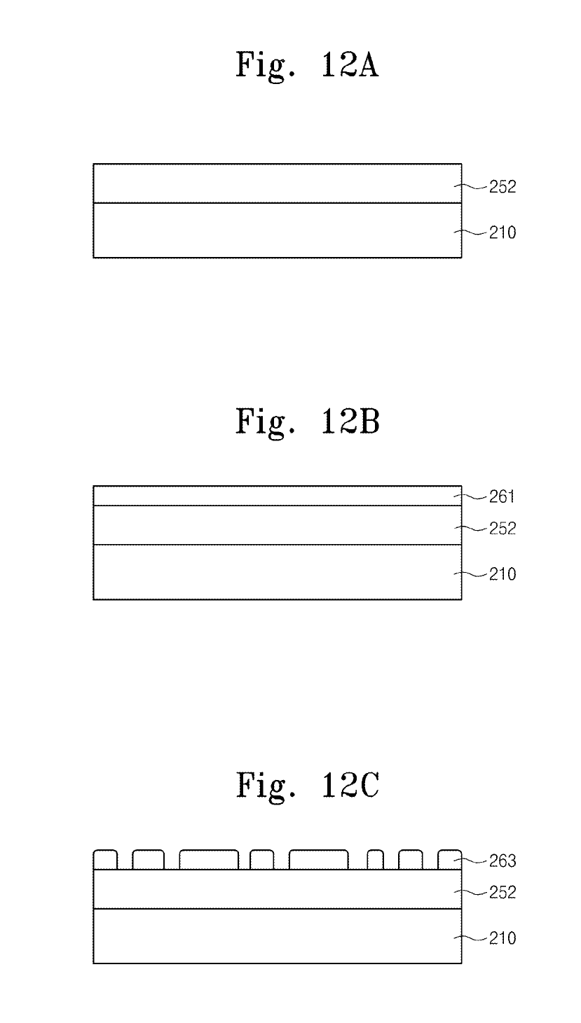

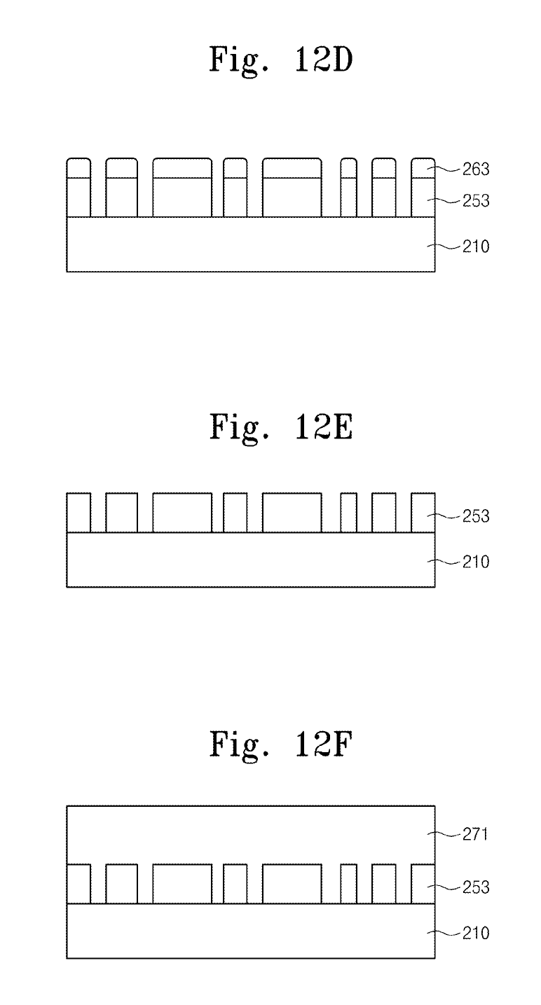

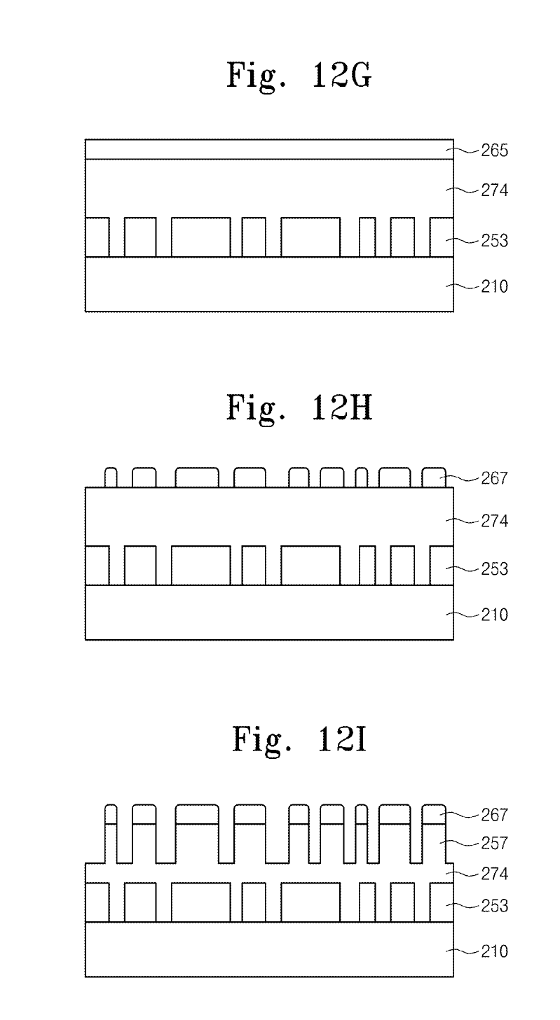

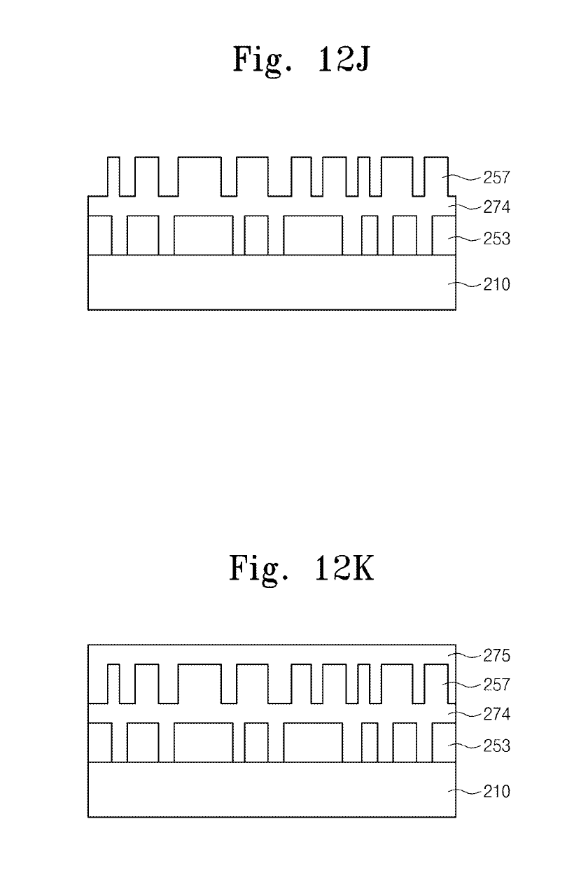

FIGS. 12A to 12K are schematic diagrams illustrating a method of fabricating an organic electroluminescent device according to other example embodiments of the inventive concept.

Firstly, referring to FIG. 12K, the first nano-sized embossing layer 253 may be deposited on the substrate 210.

The first planarization layer 274 may be deposited on the first nano-sized embossing layer 253.

The first planarization layer 274 may be etched to form the second nano-sized embossing layer 257.

The second planarization layer 275 may be deposited on the second nano-sized embossing layer 257.

For example, a detailed process may be as follows:

Referring to 12A, the first high refractive index medium layer 252 may be deposited on the substrate 210.

Referring to 12B, the first metal layer 261 may be deposited on the first high refractive index medium layer 252.

Referring to 12C, the first metal layer 261 may be thermally treated, and thus, the first nano pattern 263 may be formed as the result of a dewetting phenomenon.

Referring to 12D, the first high refractive index medium layer 252 may be etched using the first nano pattern 263 as an etch mask, thereby forming the first nano-sized embossing layer 253.

Referring to 12E, the first nano pattern 263 may be removed.

According to the afore-described embodiments, the first nano-sized embossing layer 253 having a high refractive index may be formed on the substrate 210, but example embodiments of the inventive concepts may not be limited thereto. For example, the first nano-sized embossing layer 253 may be formed by patterning or processing the substrate 210, such that the first nano-sized embossing layer 253 may be provided as a part of the substrate 210.

Referring to 12F, the first planarization layer 274 may be deposited on the first nano-sized embossing layer 253. The thickness of the first planarization layer 274 may be a thickness added with a height of the second nano-sized embossing layer.

Referring to 12G, the second metal layer 265 may be deposited on the first planarization layer 274.

Referring to 12H, the second metal layer 265 may be thermally treated, and thus, the second nano pattern 267 may be formed as the result of the dewetting phenomenon. Unlike the process described with reference to FIGS. 11A to 11L, the second nano pattern 267 may be directly formed on the first planarization layer 274 without the second high refractive index medium layer 255(refer to 11I).

Referring to 121, the first planarization layer 274 may be etched using the second nano pattern 267 as an etch mask to form the second nano-sized embossing layer 257. In other words, the second nano-sized embossing layer 257 may be provided as a part of the first planarization layer 274.

Referring to 12J, the second nano pattern 267 may be removed.

Referring to 12K, the second planarization layer 275 may be deposited on the second nano-sized embossing layer 257.

As the result of the above processes, the organic electroluminescent device may be fabricated to have the structure shown in FIG. 10.

According to example embodiments of the inventive concept, the organic electroluminescent device may include a plurality of nano-sized embossing layers improving light extraction, and thus, it has improved light extraction efficiency.

While example embodiments of the inventive concepts have been particularly shown and described, it will be understood by one of ordinary skill in the art that variations in form and detail may be made therein without departing from the spirit and scope of the attached claims.

What is claimed is:

1. An organic electroluminescent device, comprising:
an organic electroluminescent layer emitting a light;
a plurality of nano-sized embossing layers stacked to improve light extraction efficiency of the emitted light;and
at least one planarization layer covering a corresponding one of the nano-sized embossing layers.

2. The device of claim 1, wherein the nano-sized embossing layers comprises convex portions, whose width ranges from 100 nm to 1000 nm.

3. The device of claim 1, wherein the nano-sized embossing layers comprises convex portions, whose space ranges from 100 nm to 3000 nm.

4. The device of claim 1, wherein the nano-sized embossing layers comprise at least one of SiO₂, SnO₂, TiO₂, TiO₂—SiO₂, ZrO₂, Al₂O₃, HfO₂, In₂O₃, ITO, nitride, polyethylene resin, poly acryl resin, polyvinyl chloride (PVC) resin, polyvinylpyrrolidone (PVP), polyimide resin, polystyrene resin, epoxy resin, or silicone resin.

5. The device of claim 1, wherein the nano-sized embossing layers are formed as a part of the planarization layer.

6. The device of claim 1, wherein the planarization layer has a refractive index ranging from 1.2 to 2.5.

7. The device of claim 1, wherein one of the at least one planarization layer has a refractive index ranging from 1.7 to 2.5 and is disposed under an electrode for supplying holes to the organic electroluminescent layer.

8. The device of claim 1, wherein a refractive index of the at least one planarization layer increases with decreasing distance from the organic electroluminescent layer.

9. The device of claim 1, wherein a refractive index of each planarization layer is higher than that of the nano-sized embossing layers.

10. The device of claim 1, wherein the planarization layer comprises at least one of inorganic materials, polymers, or composites of inorganic material and polymer,
the inorganic materials comprises at least one of TiO₂, TiO₂—SiO₂, ZrO₂, ZnS, SnO₂, or In₂O₃, and
the polymers comprises at least one of polyvinyl phenol resin, epoxy resin, polyimide resin, polystyrene resin, polycarbonate resin, polyethylene resin, PMMA resin, polypropylene resin, or silicone resin.

11. An organic electroluminescent device, comprising a plurality of nano structures, each of which includes a nano-sized embossing layer and a planarization layer covering the nano-sized embossing layer, and which are stacked one on another.

12. A method of fabricating an organic electroluminescent device, comprising:
forming a first nano-sized embossing layer on a substrate;
forming a first planarization layer on the first nano-sized embossing layer;
forming a second nano-sized embossing layer on the first planarization layer; and
forming a second planarization layer on the second nano-sized embossing layer.

13. The device of claim 12, wherein the forming first nano-sized embossing layer comprises:
forming a first high refractive index medium layer on the substrate;
forming a first metal layer on the first high refractive index medium layer;
thermally treating the first metal layer to form a first nano-sized pattern as the result of dewetting phenomenon;
etching a portion of the first high refractive index medium layer exposed by the first nano pattern to form a first nano-sized embossing layer; and
removing the first nano pattern, the forming second nano-sized embossing layer comprises:
forming a first planarization layer on the first nano-sized embossing layer;
forming a second high refractive index medium layer on the first planarization layer;
stacking a second metal layer on the second high refractive index medium layer;
thermally treating the second metal layer to form a second nano pattern as the result of dewetting phenomenon;
etching a portion of the second high refractive index medium layer exposed by the second nano pattern to form a second nano-sized embossing layer; and
removing the second nano pattern.

14. A method of fabricating an organic electroluminescent device, comprising:
forming a first nano-sized embossing layer on a substrate;
forming a first planarization layer on the first nano-sized embossing layer;
etching the first planarization layer to form a second nano-sized embossing layer; and
forming a second planarization layer on the second nano-sized embossing layer.

15. The device of claim 14, wherein the forming first nano-sized embossing layer comprises:
forming a first high refractive index medium layer on the substrate;
forming a first metal layer on the first high refractive index medium layer;
thermally treating the first metal layer to form a first nano pattern as the result of dewetting phenomenon;
etching a portion of the first high refractive index medium layer exposed by the first nano pattern to form a first nano-sized embossing layer; and
removing the first nano pattern, the forming second nano-sized embossing layer comprises:
forming a second metal layer on the first planarization layer;
thermally treating the second metal layer to form a second nano pattern as the result of dewetting phenomenon;
etching a portion of the first planarization layer exposed by the second nano pattern to form a second nano-sized embossing layer; and
removing the second nano pattern.
